(19) United States
(12) Patent Application Publication
(10) Pub. No.: US 2013/0174896 A1
(43) Pub. Date: Jul. 11, 2013

(54) TANDEM SOLAR CELL USING A SILICON MICROWIRE ARRAY AND AMORPHOUS SILICON PHOTOVOLTAIC LAYER

(71) Applicants: Shane Ardo, Pasadena, CA (US); Nathan S. Lewis, La Canada, CA (US)

(72) Inventors: Shane Ardo, Pasadena, CA (US); Nathan S. Lewis, La Canada, CA (US)

(73) Assignee: CALIFORNIA INSTITUTE OF TECHNOLOGY, Pasadena, CA (US)

(21) Appl. No.: 13/539,335

(22) Filed: Jun. 30, 2012

Related U.S. Application Data
(60) Provisional application No. 61/503,083, filed on Jun. 30, 2011.

(51) Int. Cl. H01L 31/0725

(52) U.S. Cl. CPC H01L 31/0725
USPC 136/255

(57) ABSTRACT

This invention relates to photovoltaic cells, devices, methods of making and using the same.

### CROSS REFERENCE TO RELATED APPLICATIONS

This application claims priority to U.S. Provisional Application Ser. No. 61/503,083, filed Jun. 30, 2011, the disclosure of which is incorporated herein by reference.

### TECHNICAL FIELD

This invention relates to photovoltaic cells, devices, methods of making and using the same.

### BACKGROUND

Ordered arrays of crystalline-Si (c-Si) microwires, fabricated by the chemical-vapor-deposition, vapor-liquid-solid (CVD-VLS) growth mechanism, were pioneered nearly five years ago for sunlight-to-electrical power conversion. P-type Si microwire arrays, employing a thin n⁺-doped emitter layer to form a buried junction (n⁺p-Si), have since realized sunlight-to-electrical power-conversion efficiencies>7% from solid-state photovoltaic (PV) devices, and >5% power-conversion efficiency toward H₂ evolution from acidic aqueous electrolytes when functionalized with Pt electrocatalysts. In the absence of additional processing-intensive steps for light absorption enhancement, these devices demonstrated a short-circuit (maximum) current density (j_{sc})≈9 mA/cm², open-circuit (maximum) photopotential (V_{oc})≈0.53 V, and fill factor≈70%. The product of these three terms determines the power-conversion efficiency of the device. The Si microwire geometry uses ˜5% of the material required for conventional wafer-based photovoltaics (PVs) and absorbs ˜20% of above bandgap sunlight. Various designs to alter the path of light and increase absorption by the Si microwire arrays, and thus j_{sc} and the efficiency, have been investigated with modest success. Thus, the problem to-date is that with solely a single Si microwire array, increasing the efficiency beyond ˜7% is difficult.

### SUMMARY

The disclosure provides a microstructure for converting solar energy to electricity comprising an array of semiconducting microwires on a substrate and comprising one or more silicon-based semiconductive materials having different band-gaps in intimate electrical contact with the microwires. In one embodiment, the array of microwires are crystalline silicon. In another embodiment, the one or more silicon-based semiconductive materials form p-n junctions with the microwires. In any of the foregoing embodiments, a microwire of the array of microwires has a dimension comprising 500 nm to about 10 micrometers in diameter and about 1 micrometer to 1 mm in length. In further embodiments of any of the foregoing, the microwires and the substrate are the same material. In other embodiments, the microwire and the substrate are p-type (or n-type) crystalline silicon. In one embodiment, the one or more silicon-based semiconductive materials comprises an n⁺-type (or p⁺-type, respectively) silicon layer on the radial surface of a microwire. In another embodiment, an end of a microwire distal from the substrate comprises one or more silicon-based semiconductive materials with a different band-gap forming a cap on the microwire forming a buried junction. In a further embodiment, the one or more silicon-based semiconductive materials at the end of the microwire is an amorphous p⁺-type (or n⁺-type, respectively) silicon material. In yet another embodiment, the array further comprises an additional undoped and then n-type (or p-type, respectively) amorphous silicon on top of the prior a-Si. In yet another embodiment, a portion of the array of microwires is embedded in a polymer, glass, or wax. In some embodiments, the polymer is a conductive polymer. In embodiments comprising a cap, the cap further comprises a metal catalyst for performing electrochemical fuel-forming reactions.

The disclosure also provides a wire array structure for converting solar energy to electricity comprising (a) a plurality of semiconductor silicon microwires each comprising 500 nm to about 10 micrometers in diameter and about 1 micrometer to 1 mm in length; and (b) a silicon layer deposited on said plurality of wires, said layer comprising a wider band-gap than the silicon microwires and forming a p-n junction with the microwire, wherein said layer is conformal to said plurality of wires.

The disclosure also provides a solar cell comprising the structure and embodiments described above.

In another embodiment, the disclosure provides a device or photocell comprising a substrate; an ordered array of elongate semiconductor structures, wherein the elongate semiconductor structures have length dimensions defined by adjacent ends in electrical contact with at least portions of the substrate and distal ends not in contact with the substrate and have radial dimensions generally normal to the length dimensions and the radial dimensions are less than the length dimensions; and a silicon material layer coated on the elongated semiconductor structure to for a p-n junction, wherein at least some portions of the layer are in electrical contact with one or more elongate semiconductor structures of the plurality of the elongate semiconductor structures along at least portions of the length dimensions of the one or more elongate semiconductor structures, wherein the device absorbs received light and converts it into electricity or chemical fuels via electrochemical reactions at their surfaces. In one embodiment, the elongated semiconductor structures comprise wires. In another embodiment, the elongate semiconductor structures are grown from the substrate; deposited on the substrate; or formed by etching the substrate. In yet another embodiment, the elongate semiconductor structures are embedded in a matrix such as a glass, polymer or wax. In some embodiments, the elongate semiconductor structures are partially or fully embedded in a matrix. In other embodiments, the substrate is removed.

### BRIEF DESCRIPTION OF THE DRAWINGS

FIG. 1 shows an arrangement and use of a c-Si microwire array with a thin a-Si direct-bandgap material deposited on its surface.

### DETAILED DESCRIPTION

As used herein and in the appended claims, the singular forms “a,” “and,” and “the” include plural referents unless the context clearly dictates otherwise. Thus, for example, reference to “a pillar” includes a plurality of such pillars and reference to “the catalyst” includes reference to one or more catalysts known to those skilled in the art, and so forth.

Also, the use of “or” means “and/or” unless stated otherwise. Similarly, “comprise,” “comprises,” “comprising” “include,” “includes,” and “including” are interchangeable and not intended to be limiting.

It is to be further understood that where descriptions of various embodiments use the term “comprising,” those skilled in the art would understand that in some specific instances, an embodiment can be alternatively described using language “consisting essentially of” or “consisting of.”

Unless defined otherwise, all technical and scientific terms used herein have the same meaning as commonly understood to one of ordinary skill in the art to which this disclosure belongs. Although methods and materials similar or equivalent to those described herein can be used in the practice of the disclosed methods and compositions, the exemplary methods, devices and materials are described herein.

The publications discussed above and throughout the text are provided solely for their disclosure prior to the filing date of the present application. Nothing herein is to be construed as an admission that the inventors are not entitled to antedate such disclosure by virtue of prior disclosure.

By “about” is meant a quantity, level, value, number, frequency, percentage, dimension, size, amount, weight or length that varies by as much as 30, 25, 20, 15, 10, 9, 8, 7, 6, 5, 4, 3, 2 or 1% to a reference quantity, level, value, number, frequency, percentage, dimension, size, amount, weight or length. With respect to ranges of values, the invention encompasses each intervening value between the upper and lower limits of the range to at least a tenth of the lower limit's unit, unless the context clearly indicates otherwise. Further, the invention encompasses any other stated intervening values. Moreover, the invention also encompasses ranges excluding either or both of the upper and lower limits of the range, unless specifically excluded from the stated range.

The term “array” generally refers to multiple numbers of structures distributed within an area and spaced apart, although possible touching in some places, unless otherwise indicated. Structures within an array all do not have to have the same orientation.

The term “aspect ratio” refers to the ratio of a structure's length to its width. Hence, the aspect ratios of the elongate structures will be greater than one. In various embodiments, the diameter of, for example, a “rod” or “wire” is about 10-50 nm, about 50-100 nm, about 100-500 nm, about 500 nm-1 μm, about 1 μm-10 μm or about 10μ-100 μm. Typically the diameter will be about 1-10 μm. The length of the “rod” or “wire” is about 1 μm-10 μm, about 10 μm-100 μm, or about 100 μm-several millimetres.

The terms “ball,” “spheroid,” “blob” and other similar terms may also be used synonymously, except as otherwise indicated. Generally, these terms refer to structures with the width defined by the longest axis of the structure and the length defined by the axis generally normal to the width. Hence, the aspect ratio of such structures will generally be unity or less than unity.

The terms “ordered” or “well-defined” generally refer to the placement of elements in a specified or predetermined pattern where the elements have distinct spatial relationships to one another. Hence, the terms “ordered array” or “well-defined” generally refer to structures distributed within an area with distinct, specified or predetermined spatial relationships to one another. For example, the spatial relationships within an ordered array may be such that the structures are spaced apart from one another by generally equal distances. Other ordered arrays may use varying, but specified or predetermined, spacings. The structures within “ordered” or “well-defined” arrays may also have similar orientations with respect to each other.

A “photovoltaic cell” is an electrical device comprising a semiconductor that converts light or other radiant energy, in the range from ultraviolet to infrared radiation, incident on its surface into electrical energy in the form of power/voltage/current and which has two electrodes, usually at least one diode where the diode has a top electrode and a bottom electrode with opposite electrical polarities. The photovoltaic cell produces direct current which flows through the electrodes. As employed herein, the term photovoltaic cell is generic to cells which convert radiant energy into electrical energy. A solar cell is a photocell that converts light including solar radiation incident on its surface into electrical energy.

A photovoltaic (“PV”) cell may be connected in parallel, in series, or a combination thereof with other such cells. A common PV cell is a p-n junction device based on crystalline silicon. In various embodiments of the disclosure a PV cell comprises p-n junction devices of silicon microwires. In other embodiments a PV cell comprises a plurality of silicon p-n junctions. Other types of PV cells can be based on a p-n junction cell of silicon and other semiconductive materials, such as, but not limited to, amorphous silicon, polycrystalline silicon, germanium, organic materials, Group III-V semiconductor materials, such as gallium arsenide (GaAs), Group II-VI semiconductor materials, such as cadmium sulfide (CdS), metal oxides, nitrides, or chalcogenides, such as zinc oxide, and mixed ternary, and larger number component, materials.

During operation of a photovoltaic cell, incident solar or light radiation penetrates below a surface of the PV cell and is absorbed. The depth at which the solar radiation penetrates depends upon an absorption coefficient of the cell. In the case of a PV cell based on silicon, an absorption coefficient of silicon varies with wavelength of solar radiation. At a particular depth within the PV cell, absorption of solar radiation produces charge carriers in the form of electron-hole pairs. Electrons flow through one electrode connected to the cell, while holes exit through another electrode connected to the cell. The effect is a flow of an electric current through the cell driven by incident solar radiation. Inefficiencies exist in current solar cells due to the inability to collect/use and convert the entire incident light.

Also, in accordance with a junction design of a PV cell, charge separation of electron-hole pairs is typically confined to a depletion region, which can be limited to a thickness of about 1 μm. Electron-hole pairs that are produced further than a diffusion or drift length from the depletion region typically do not charge separate and, thus, typically do not contribute to the conversion into electrical energy. The depletion region is typically positioned within the PV cell at a particular depth below a surface of the PV cell. The variation of the absorption coefficient of silicon across an incident solar spectrum can impose a compromise with respect to the depth and other characteristics of the depletion region that reduces the efficiency of the PV cell. For example, while a particular depth of the depletion region can be desirable for solar radiation at one wavelength, the same depth can be undesirable for solar radiation at a shorter wavelength. In particular, since the shorter wavelength solar radiation can penetrate below the surface to a lesser degree, electron-hole pairs that are produced can be too far from the depletion region to contribute to an electric current.

A photoelectrochemical (PEC) cell is a PV cell immersed in an electrolyte to impart electrochemical reactions at its surfaces. It is generally equivalent to electrically connecting a PV cell to two electrodes immersed in an electrolyte such that the electrochemical reactions are directly driven by the electricity generated by the PV. A photoelectrosynthetic (PES) cell is one where the net reactions being driven by the PV cell are thermodynamically unfavorable and thus require the free energy of the PV to perform the reactions. There are two electrochemical reactions, termed half-reactions, that occur, one at each electrode, to result in an overall balanced chemical reaction, such as the water splitting reaction which is 2H₂O→2H₂+O₂.

N/P junction refers to a connection between a p-type semiconductor and an n-type semiconductor which produces a diode. Depletion region refers to the transition region between an n-type region and a p-type region of an N/P junction where a high electric field exists.

Electromagnetic Radiation to Electric Energy Conversion Device (EREECD) is a device that reacts with electromagnetic (optical) radiation to produce electrical energy. Optoelectronic Energy Device (OED) refers to a device that reacts with optical radiation to produce electrical energy with an electronic device. As used herein, the term “ultraviolet range” refers to a range of wavelengths from about 5 nm to about 400 nm. As used herein, the term “visible range” refers to a range of wavelengths from about 400 nm to about 700 nm. As used herein, the term “infrared range” refers to a range of wavelengths from about 700 nm to about 2 mm. The infrared range includes the “near infrared range,” which refers to a range of wavelengths from about 700 nm to about 5 μm, the “middle infrared range,” which refers to a range of wavelengths from about 5 μm to about 30 μm, and the “far infrared range,” which refers to a range of wavelengths from about 30 μm to about 2 mm.

Multi-junction solar cells or tandem cells are solar cells containing several p-n junctions. Each junction can be tuned to a different wavelength of light, reducing one of the largest inherent sources of losses, and thereby increasing efficiency. Traditional single-junction cells have a maximum theoretical efficiency of about 34%, a theoretical “infinite-junction” cell would improve this to 87% under highly concentrated sunlight.

Within this description, the term “semiconductive material”, “semiconductor” or “semiconducting substrate” and the like is generally used to refer to elements, structures, or devices, etc. comprising materials that have semiconductive properties, unless otherwise indicated. Such materials include, but are not limited to: materials including elements from Group IV of the periodic table; materials including elements from Group III and Group V of the periodic table; materials including elements from Group II and Group VI of the periodic table; materials including elements from Group I and Group VII of the periodic table; materials including elements from Group IV and Group VI of the periodic table; materials including elements from Group V and Group VI of the periodic table; and materials including elements from Group II and Group V of the periodic table. Other materials with semiconductive properties may include: layered semiconductors; metallic alloys; miscellaneous oxides; some organic materials, and some magnetic materials. The term “semiconducting structure” refers to a structure consisting of, at least in part, a semiconducting material. A semiconducting structure may comprise either doped or undoped material.

Further the term “vertical” with reference to wires, rods, whiskers, pillars, etc., generally refers to structures that have a length direction that is elevated somewhat from horizontal.

The term “vertical alignment” generally refers to an alignment or orientation of a structure or structures that is elevated from horizontal. The structure or structures do not have to be completely normal to horizontal to be considered to have a vertical alignment.

The terms “vertically aligned array” or “vertically oriented array” generally refer to arrays of structures where the structures have orientations elevated from a horizontal orientation up to orientations completely normal to a horizontal orientation, but the structures within the array may or may not have all the same orientations with respect to horizontal.

The term “wider band-gap” refers to the difference in band-gaps between a first sub-cell (or first material) and a second sub-cell (or second material). “Band-gap” or “energy band gap” refers to the characteristic energy profile of a semiconductor that determines its electrical performance, current and voltage output, which is the difference in energy between the valence band maximum and the conduction band minimum. For example, in one embodiment, reference to a wire coated with a material having a “wider band-gap material” refers to a material having a wider band-gap than the wire's material.

Within this description, the terms “wires,” “rods,” “whiskers,” and “pillars” and other similar terms may be used synonymously, except as otherwise indicated. Generally, these terms refer to elongate structures which have lengths and widths, where the length is defined by the longest axis of the structure and the width is defined by the axis generally normal to the longest axis of the structure.

Embodiments of the disclosure comprise microwires comprising a plurality of p-n junctions. In one embodiment, a microwire of the disclosure comprises at least two p-n junctions. In another embodiment, the microwire comprises 3 or more p-n junctions. A multijunction (sometimes referred to as a tandem junction) device consisting of at least one Si microwire array and another photopotential generating junction connected intimately and electrically in series will improve efficiency and the maximum photopotential, i.e. V_{oc}, will also greatly increase. This is important for photoelectrosynthetic systems, where the energy in sunlight is directly converted into chemical fuel. For example, in some instances potentials larger than the V_{oc} of a single Si microwire array are required, e.g. H₂/Br₃⁻ from HBr; H₂/Cl₂ from HCl; H₂/O₂ from H₂O, and other reactions where the reduced species contains hydrocarbon and the precursor is CO₂ or carbonic acid or its salts.

In one embodiment, the disclosure provides a crystalline Si (c-Si) microwire array with a thin, buried-junction amorphous Si (a-Si) photovoltaic deposited on the c-Si microwire. This will result in a V_{oc} that is the sum of the photopotentials at each junction and will double the device efficiency and V_{oc}, while maintaining the same j_{sc}, affording a significant photopotential that can drive unassisted H₂ evolution from fuming HBr electrolytes via photoelectrosynthesis.

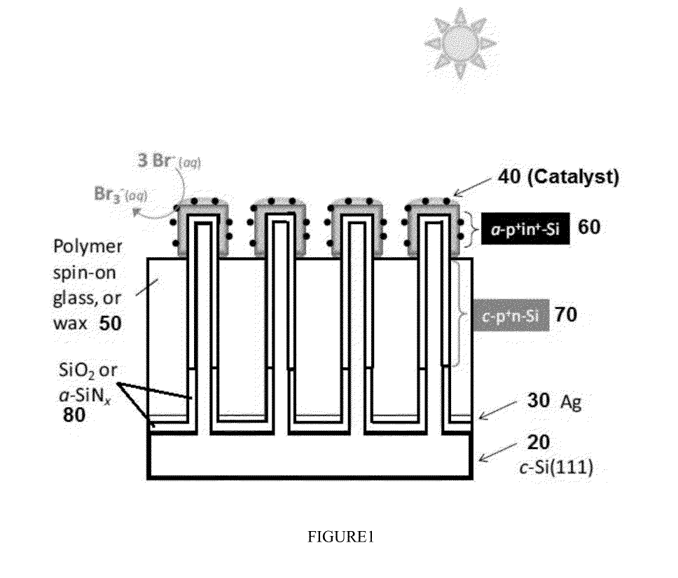

For example, n-type c-Si microwire arrays will be fabricated (n-Si) as described more thoroughly below. Then, a buried-junction will be fabricated as a thin p⁺ emitter layer (p⁺n-Si), using, for example, a boron-nitride/-oxide thermal diffusion source wafer. Low-temperature plasma-enhanced CVD (PECVD), hot-wire CVD (HWCVD), and/or magnetron sputtering can be employed to deposit a thin (˜1 μm) layer of a-Si as a-n⁺-Si (<100 nm) followed by intrinsic a-i-Si and then a-p⁺-Si (<100 nm). This would result in two p-n junctions connected both optically and electrically in series, one in the c-Si region and the other in the a-Si region, with an intervening low-resistance tunnel junction between them (see FIG. 1).

Various embodiments of the invention are set forth in FIG. 1. FIG. 1 shows an arrangement and use of a c-Si (20) microwire array with a thin a-Si direct-bandgap material (60) deposited on its surface; a silver back reflector (30) is shown. In one embodiment, the microwire array can be embedded in a glass, polymer wax or other material (50) (e.g., Nafion®) and mechanically peeled from the substrate to make a free-standing device. This free-standing device can be contacted electrically to external leads, thus forming a PV cell, or immersed in an electrolyte, after possible deposition of appropriate electrocatalysts, to form a PES cell. Also, ITO could be deposited on the top of this device to make a solid-state PV. In addition, as stated herein, the c-Si microwires (20) can be made with an nip structure and/or as an axial-junction device and/or employing a-SiNx as the coating (80) on the outside of the wires to serve as a surface passivation layer and an antireflective coating. Furthermore, all of the p-type doped regions could be changed to n-type and vice versa. Any of these architectures should greatly improve the overall power-conversion efficiency of the device. In yet another embodiment, a catalyst (40) (e.g., Pt, Ni, Ni—Mo, MoS₂ or the like) can be coated on the device to facilitate H₂ production from H₂O, or other electrochemical half-reactions resulting in a photoelectrosynthetic cell.

The disclosure also provides other compositional analogs; for example, the a-p⁺in⁺-Si layer (60) could be deposited along the entire surface of the buried-junction c-Si microwire array, coating it fully. Alternatively, an axial-junction c-Si microwire array with a c-n⁺-Si growth wafer (and back surface field), intrinsic bulk c-i-Si microwire, and c-p⁺-Si top, coated along the sides with silicon nitride (a-SiNₓ), would allow for a smaller junction contact area and a larger V_{oc} from the Si microwire array junction. In this instance the a-p⁺in⁺-Si layer would be deposited on the tops of the microwires for a tandem PV with smaller contact areas for recombination and thus larger photopotentials than the device described with the larger junction area. Any of the above architectures can employ entirely opposite doping configurations, i.e. p/p⁺ for n/n⁺ and vice versa.

Embodiments of the disclosure provide structures that are particularly useful for devices such as solar cells, electronic devices, photonic materials that utilize optical properties of periodic structures of light-absorbing or light-directing materials arranged with structural order in another optically different material, sensors, fuel-forming artificial photoelectrosynthetic solar fuels devices, and similar chemical, optical, and electronic devices and structures.

Embodiments of the disclosure comprise wire arrays or other semiconducting structures with control of the size, position, and uniformity of the fabricated wire arrays or structures over a relatively wide area wherein the arrays comprise wires having tandem or multijunction modes. Such wire arrays or structures can comprise crystalline Si wires of a length long enough to absorb a significant fraction of above-bandgap sunlight, each wire with a radius matched to its diffusion length, and the wires being regularly spaced, and oriented predominantly vertically, typically over large areas. As mentioned above, the dimensions of the underlying wire arrays are typically from about 1-10 μm in diameter and 10-100 μm or greater in length. Embodiments of the disclosure may comprise growing the wire arrays or structures through VLS processes.

Such wire arrays or structures comprise, in one embodiment, crystalline Si wires of a length long enough to absorb a significant fraction of above-bandgap sunlight, each wire with a radius matched to its diffusion length, and the wires being regularly spaced, and oriented predominantly vertically, typically over large areas. Embodiments of the disclosure can comprise growing the wire arrays or structures through VLS processes. In such an embodiment, a templating layer is first patterned with openings (e.g., an array of holes) in which the wires or structures are to be grown. The templating layer comprises a diffusion barrier for a deposited catalyst. The diffusion barrier may comprise a patterned oxide layer, a patterned insulating layer, such as a layer comprising silicon nitride, a patterned metal layer, or combinations of these materials or other materials or processes that facilitate the deposition of the catalyst for semiconductor structure growth. The catalyst is then deposited in the openings. Wires or structures are then grown on the substrate by heating the substrate and applying a growth gas.

In one embodiment, a Si <111> wafer is used as the material from which the wire arrays are grown. Other materials may also be used to support wire growth, such as a thin Si layer disposed on glass, or other such Si substrates. All or portions of the wafer may be doped. For example, some embodiments may use a degenerately doped n-type Si wafer. In the process a surface oxide layer is thermally grown on the wafer. In one embodiment, the surface oxide layer is grown to a thickness of 285 nm. In another embodiment, the surface oxide layer is grown to a thickness of 300 nm. Other embodiments may comprise oxide layers at other thicknesses. Still other embodiments have the oxide layer deposited via chemical vapor deposition (CVD) or other methods known in the art.

A photoresist layer is applied to support the development of a patterned template as discussed below. However, other materials and techniques for creating a patterned template may be used, such as a latex layer, or stamping or soft lithography. The photoresist layer may comprise S1813 photoresist from MicroChem. Corp. (Newton, Mass., USA) or other photoresist material. The photoresist layer is then exposed to ultraviolet-to-visible light through a desired array pattern and developed with a developer to form a desired pattern of holes in the resist layer. The developer may comprise MF-319 or other developers known in the art. The patterned resist layer is then used to etch the oxide layer on the Si wafer. Etching of the oxide layer may be achieved by using hydrofluoric acid compositions such as buffered HF (9% HF, 32% NH₄F) from Transene Company, Inc. (Danvers, Mass., USA). Other etching techniques known in the art may also be used to etch the oxide layer. The result of the etching will be a pattern of holes in the oxide layer. A pattern of holes may be, for example, a square array of 3 μm diameter holes that are 7 μm center to center.

A growth catalyst is then thermally evaporated onto the resist layer and into the holes in the oxide layer. Other methods of depositing the catalyst may be used, such as electrodeposition. Typical catalysts comprise gold, copper, or nickel, but other metals known in the art as Si V-L-S catalysts may be used, such as platinum or aluminum. For example, 500 nm of gold may be thermally evaporated onto the resist layer and into the holes. Lift-off of the photoresist layer is then performed, leaving catalyst islands separated by the oxide in the oxide layer.

The wafer with the patterned oxide layer and the deposited catalyst may then be annealed. Typically, the annealing is performed in a tube furnace at a temperature between 900 to 1000° C. or at a temperature of about 1050° C. for 20 minutes with the application of 1 atm of H₂ at a flow rate of 1000 sccm (where SCCM denotes cubic centimeters per minute at STP). Growth of wires on the wafer is then performed. Typically, the wires are grown in a mixture of H₂ (1000 sccm) and SiCl₄ (20 sccm) at about 1 atm. In one embodiment, the wires are grown for between 20 to 30 minutes at temperatures between 850° C. to 1100° C. Other embodiments may use different growth times, pressures, and or flow rates. However, optimal growth temperatures are between 1000° C. and 1050° C. Growth for these times and at these temperatures may produce wires from 10 μm to 30 μm in length or longer.

Following the growth of the wires, the oxide layer may be removed. It is not necessary for the oxide layer to be removed, however, it is beneficial to remove the oxide layer if a-SiNx is to be deposited. Typically, the oxide layer is removed after the emitter is formed. The emitter is formed after oxidizing the wires and using an infilled polymer to cover the bottom of the oxide and selectively etch the oxide at the tops of the wires. This occurs prior to emitter formation to help prevent shunts from the emitter to the base of the wire or the growth substrate. Also, when growing n-type Si micro-wires, oxidation is performed along with the polymer infill step as the VLS growth process is accompanied by a VS deposition of phosphorus from PH₃ on the micro-wire sidewalls. The oxide layer may be removed by etching the wafer for 10 seconds in 10% HF (aq) or other methods known in the art may be used to remove the oxide layer. Growth catalyst particles may remain at the top of each grown wire, which may impact the functionality of the resulting wire array. Therefore, it may be advantageous to remove the catalyst particles. For example, if the catalyst comprises Au, the gold particles may be removed by soaking the wafer 10 for 10 min in a TFA solution from Transene Company, Inc., which contains I⁻/I₃⁻. Other methods known in the art may also be used to remove catalyst particles.

According to an embodiment of the disclosure, photolithography is a suitable method for enabling uniform arrays of wires of diameters of ˜1 μm to be grown over large areas. In cost sensitive applications such as photovoltaics, it may be desirable to employ lower-cost lithographic methods, and embodiments of the disclosure are readily extendable to alternative patterning techniques such as nanoimprint lithography.

Cost also motivates the use of non-Au catalysts for embodiments according to the disclosure. As indicated above, Cu, Ni, Pt, or Al may be used as a catalyst for Si wire growth. Cu is, unlike Au, an inexpensive, earth-abundant material, and, therefore, of particular interest for such embodiments. Although Cu is more soluble in Si than Au and is also a deep trap, Si solar cells are more tolerant of Cu contamination than of Au, and thus diffusion lengths of at least microns even in the case of Cu catalyzed growth can be expected.

The method described above has been shown to produce nearly defect-free arrays that exhibited an extremely narrow diameter and length distribution, and highly controlled wire position.

As discussed above, other growth catalysts may be used to facilitate the growth of the Si wires in the wire array. Nominally identical wire arrays may be obtained when Cu, Ni, Pt, or Al (or other Si growth catalyst metals) are used as the VLS growth catalyst instead of Au.

Use of the oxide layer is particularly useful in some embodiments of the disclosure. For example, Si wire arrays did not yield high pattern fidelity when the catalyst was not confined using the patterned oxide layer as described above.

The ordered array of rods/wires can then be embedded in a matrix material (e.g., glass, wax or a polymer). The array can be embedded to substantially cover the whole length of the wires (e.g., 1-100% of the length), or may be only partially embedded (e.g., 99% or less). The matrix can be useful for removing the array of wires from a substrate. In another embodiment, the array of wires is first processed to provide a p-n junction with, for example, a p-emitter layer on an n-type crystalline microwire prior to embedding the wire array in the matrix material.

In one embodiment, the ordered array of rods/wires is layered with a material to form one or more p-n junctions comprising a wider band gap material. For example, the crystalline n-type silicon rods/wires can be layered with a p⁺-emitter layer using methods such as molecular beam epitaxy (MBE) or metal organic chemical vapor deposition (MOCVD). In another embodiment, sputtering can be used to deposit an amorphous silicon emitter on the microwires.

Thus, in one embodiment the disclosure provides an array of rods/wires comprising Si having dimensions of about 1-10 micrometers in diameter and about 1 micrometer to about 100 μm in length coated with one or more layers of the opposite (p/n)-type silicon to form a p-n junction. In some embodiments, the array of rods/wires is generated on a substrate. In other embodiments, the array is coated or treated to provide multiple junctions and then removed from the substrate. In yet another embodiment, the array is coated or treated to provide multiple junctions and then the rods/wires are embedded in a polymer material to maintain organization upon removal of the array from a substrate.

A particular application for wire arrays fabricated according to embodiments of the disclosure is for the use of such wire arrays in photoelectrochemical cells or photoelectrosynthetic fuel-generating systems. Device analysis has shown that photovoltaic efficiency is maximized in wire arrays when the mean radius of the wires is comparable to the minority carrier diffusion length. This is because of a trade-off between increased current collection and the loss of open-circuit voltage due to the increased junction and surface area. Diffusion of gold into bulk silicon at the growth temperatures of 1000-1050° C. leads to carrier lifetimes of >1 ns, which combined with carrier mobilities expected for the observed dopant densities, indicates minority carrier diffusion lengths of ˜1 μm. However, as described above, embodiments of the disclosure provide the ability to grow relatively long wire arrays (greater than 30 μm) while maintaining a radius comparable to the minority diffusion length (on the order of 1.5 μm). In some embodiments, these arrays are coated with about 100 nm thick layer of an opposite-type Si emitter layer to give a total layered diameter of about 2.5 micrometers.

Hence, embodiments of the disclosure provide wire arrays with aspect ratios particularly suitable for use in solar cell apparatus. Further, embodiments of the disclosure provide for the ability to have relatively dense arrays of wires, further improving the ability of devices using such arrays to convert light to electrical energy.

The disclosure also provides an artificial photo(electro)synthetic system that utilizes sunlight and water, or other solutions that can be used to generate H₂, gas as inputs and produces hydrogen and, for example, oxygen as the outputs. The system comprises three distinct primary components: a photoanode, a photocathode, and a product-separating but ion-conducting membrane. These components may be fabricated and optimized separately before assembly into a complete water-splitting system. The system may incorporate two separate, photosensitive semiconductor/liquid junctions that collectively generate, for example, the 1.7-1.9 V at open circuit necessary to support both the net oxidation and reduction of, for example, water to O₂ and H₂, respectively.

The photoanode and photocathode may comprise arrays of semiconductive microwire structures of the disclosure comprising a metal catalyst on an amorphous-p⁺in⁺Si cap in tandem with the semiconductive microwire, as described above. The catalysts disposed on the semiconductive structures are used to drive the oxidation or reduction reactions at low overpotentials. Typically the catalysts coated on the semiconducting structures/substrates do not block or inhibit light energy from contacting the semiconducting wire array or substrate. Accordingly, the catalyst should cover from about 1-99% of the surface area unless sufficiently transparent to allow light penetration to the underlying semiconducting substrate. The high aspect-ratio semiconductor rod/wire electrodes allow for the use of low cost, earth abundant materials without sacrificing energy conversion efficiency due to the orthogonalization of light absorption and charge-carrier collection. Additionally, the high surface-area design of the wire-based semiconductor array electrode inherently lowers the flux of charge carriers over the rod array surface relative to the projected geometric surface of the photoelectrode, thus lowering the photocurrent density at the solid/liquid junction and thereby relaxing the demands on the activity (and cost) of the electrocatalysts. A flexible composite polymer film may be used to allow for electron and ion conduction between the photoanode and photocathode while simultaneously preventing mixing of the gaseous products. That is, the rod/wire arrays may be embedded in flexible, polymeric membrane materials, allowing the possibility of roll-to-roll system assembly. Separate polymeric materials may be used to make electrical contact between the anode and cathode, and also to provide structural support. Interspersed patches of an ion conducting polymer may be used to maintain charge balance between the two half-cells.

In a particular embodiment, the photocathode may comprise vertically (or near vertically) aligned rod/wire arrays made of macroporous p-Si <100> with a resistivity of 13-15 Ωcm and coated/capped with an amorphous p⁺-in⁺-Si cap in tandem with the microwire array.

In another embodiment, the photoanode and photocathode components may be electrically, and ionically, interconnected through, but physically separated by, a flexible composite polymer film. Further, multi-component membranes, composed of polymeric materials, that exhibit desired mechanical pliability, electronic conductivity, and ion permeability properties for a feasible water electrolysis system may be used. Specifically, polypyrrole may be used to make electrical contact between the anode and cathode, while poly(dimethylsiloxane) (PDMS) may be used to provide structural support for the semiconductor rod/wire arrays. For proton conduction in a cell operated under acidic conditions, Nafion® may be employed, whereas vinylbenzyl chloride modified films of poly(ethylene-co-tetrafluoroethylene) (ETFE), or amine-modified sulfonyl fluoride Nafion® precursors, may be used for hydroxide conduction in a cell operated under alkaline conditions.

The following examples are meant to illustrate, not limit, the disclosed invention.

### EXAMPLES

Fabrication of p-Type Si Electrodes.

Degenerately doped p-type, (111)-oriented Si wafers with p<0.005 Ωcm (p⁺-Si) are obtained from Silicon Quest International. Si microwire arrays are grown on substrates by an atmospheric pressure chemical vapor deposition (CVD) technique that used Cu as a vapor-liquid-solid (VLS) growth catalyst. For wire growth, SiCl₄(g) is the Si source and BCl₃(g) is the boron source, resulting in p-type doping of the crystalline Si microwires. After growth, the microwire array is etched to remove the Cu growth catalyst from the wire surfaces.

Catalyst Removal.

The Cu growth catalyst is removed from the tops of the Si microwires using the following procedure. First, samples are etched in 10% HF(aq) for 10 s, rinsed with >18 MΩ-cm water and dried. The samples are then submerged for 20 min in an RCA2 etching solution (6:1:1 v/v/v H₂O:HCl:H₂O₂) at 70° C., rinsed, and dried. The process is then repeated, followed by a third 10 s 10% HF(aq) etch. Finally, the samples are treated with 30 wt % KOH(aq) at room temperature for 60 s, rinsed and dried a final time.

Oxide Boot Formation.

The etched microwire arrays are thermally oxidized at 1100° C. under slow flow of ultra-high purity, research-grade Ar (2 lpm, where lpm is liters per minute) in a tube furnace for 110 min. To the resulting microwires, a polydimethylsulfoxide (PDMS) polymer solution (0.1:1:5 w/w/v of Sylgard® 184 initiator, Sylgard® 184 dimethylsulfoxide monomer, toluene) is spin-coated into the microwires at 1500 rpm for 60 s followed by a 12 hr curing in a vacuum oven at 60° C. and a 60 min cure on a hot plate at 150° C. This is followed by a brief etch of the PDMS using a tetrabutylammonium fluoride (TBAF) etch (5 sec; 3:1 v/v of N-methylpyrrolidone (NMP), aqueous TBAF) and a subsequent 5 min buffered HF etch (BOE etch from Transene), water rinse, and N₂ dry. The remaining PDMS is etched using the TBAF-NMP etch for 0.5-5 hr resulting in a microwire array with ˜200 nm less silicon on the tops and a ˜200 nm silicon oxide layer at the bottom of ˜20 μm in height; this is termed a “booted” microwire array. To this an n % emitter layer is driven into the microwires.

n⁺ Emitter Formation.

Booted microwires are cleaned via submersion in a Piranha etching solution (3:1, v/v H₂SO₄:H₂O₂), 10% HF(aq) solution, RCA1 etching solution (5:1:1 v/v/v H₂O:NH₃OH:H₂O₂) at 80° C., 10% HF(aq) solution, RCA2 etching solution (6:1:1 v/v/v H₂O:HCl:H₂O₂) at 70° C., and a 10% aqueous HF solution. After each step, the wire array is rinsed with >18 MΩ-cm water and dried. The wire arrays are positioned between PH-900 phosphorus diffusion doping source wafers (Saint-Gobain) and introduced into a tube furnace at 850° C. for 20 min. To this hydrogenated amorphous Si (a-Si:H) is deposited on the microwires.

Multijunction/Tandem Architecture Formation.

a-Si:H as p⁺-i-n⁺ is deposited using plasma-enhanced CVD (PECVD) techniques via a multi-chamber load-locked deposition system, where i stands for intrinsic. The microwire arrays are briefly etched in 10% HF(aq) solution, rinsed with >18 MΩ-cm water, and dried. The a-Si:H p %-doped layer is deposited using the conventional 13.56 MHz radio-frequency (RF) PECVD technique at deposition rates of 1 Å/s under amorphous or poly-, micro-, or nano-crystalline growth conditions. The a-Si:H i-layer is prepared at a high deposition rate of ˜8 Å/s using the very-high-frequency (VHF) PECVD technique with a frequency of 70 MHz, a plasma density of ˜0.2 W/cm², and under a low deposition pressure region. The deposition time for the a-Si:H i-layer is about 5 minutes, corresponding to a thickness of ˜240 nm. The nominal substrate temperature is in the range of 100-300° C. A high hydrogen dilution ratio R═[H₂]/[Si₂H₆] in the range of 30-100 is used. The a-Si:H n⁺-doped layer is also prepared using the conventional 13.56 MHz RF-PECVD technique at deposition rates of 1 Å/s. An indium-tin oxide (ITO) transparent, conductive front/top contact is deposited through a shadow mask by standard RF magnetron sputtering deposition techniques.

Alternative Arrangement: Fabrication of n-Type Si Electrodes.

Degenerately doped n-type, (111)-oriented Si wafers with p<0.005 Ωcm (n⁺-Si) are obtained from Silicon Quest International. Si microwire arrays are grown by the CVD technique described above. For wire growth, SiCl₄(g) is the Si source and PH₃(g) is the phosphorus source, resulting in n-type doping of the crystalline Si microwires. The conditions are varied during growth such that a short n %-doped region of Si was deposited for the first 90 s using 20 sccm PH₃. After growth, the microwire array is etched to remove the Cu growth catalyst from the wire surfaces as described above in the Catalyst Removal section. Then an oxide boot is fabricated to prevent shunt and getter surface phosphorus.

p⁺ Emitter Formation.

n-type booted microwires are cleaned as described above and then positioned between BN-975 boron diffusion doping source wafers (Saint-Gobain) and introduced into a tube furnace at 950° C. for 10 min. This is followed by a 10 sec HF(aq) etch, a low temperature thermal oxidation at 750° C. for 20 min in a tube furnace to oxidize the outer insoluble Si—B layer, and another 10 sec HF(aq) etch immediately before depositing a-Si:H. a-Si:H is deposited on the microwires, as n⁺-i-p⁺, using the same protocol, but in an alternative processing order as n⁺ then i then p⁺, as described above in the Multijunction/Tandem Architecture Formation section.

Polymer Infill, Catalyst Deposition, and Mechanical Removal of the Device for an HBr-Splitting Fuel-Forming Cell.

A thin layer of manganese oxide is deposited by atomic layer deposition (ALD) to protect the device from corrosion. Then, a Nafion® solution (8 wt % in dimethylformamide) is spin cast into the wire array at 1000 RPM for 10 sec, followed by heating at 60° C. in a vacuum oven for 40 min and then a final curing at 150° C. on a hotplate for 20 min. This process is repeated two more times to produce a ˜15 μm thick, conformal Nafion® membrane at the base of the microwires. Pt electrocatalysts are then deposited potentiostatically on the Si microwire tops and sidewalls. For p-Si-based tandem architectures, the applied potential is −300 mV vs. SCE and photoelectrochemical deposition using >850 nm light with 100-200 mC/cm², per projected area, of current passed. For n-Si-based tandem architectures, the applied potential is −1 V vs. SCE and dark electrochemical deposition for 100-200 mC/cm², per projected area, of current passed. These Nafion-embedded tandem arrays are then mechanically removed from the substrate using a Teflon-coated razor blade and immediately 5 nm of Pt is deposited on their backsides via electron-beam evaporation, with or without deposition of a thin layer of manganese oxide via ALD, prior to Pt deposition. The device is operated in a concentrated (>1 M) HBr(aq) solution.

Although a number of embodiments and features have been described above, it will be understood by those skilled in the art that modifications and variations of the described embodiments and features may be made without departing from the teachings of the disclosure or the scope of the invention as defined by the appended claims.

What is claimed is:

1. A microstructure for converting solar energy to electricity comprising
an array of semiconducting microwires on a substrate and comprising one or more silicon-based semiconductive materials having different band-gaps in intimate electrical contact with the microwires.

2. The microstructure of claim 1, wherein the array of microwires are crystalline silicon.

3. The microstructure of claim 1, wherein the one or more silicon-based semiconductive materials form p-n junctions with the microwires.

4. The microstructure of claim 1, wherein a microwire of the array of microwires has a dimension comprising 500 nm to about 10 micrometers in diameter and about 1 micrometer to 1 mm in length.

5. The microstructure of claim 4, wherein the microwires and the substrate are the same material.

6. The microstructure of claim 5, wherein the microwire and the substrate are p-type (or n-type) crystalline silicon.

7. The microstructure of claim 6, wherein the one or more silicon-based semiconductive materials comprises an n⁺-type (or p⁺-type, respectively) silicon layer on the radial surface of a microwire.

8. The microstructure of claim 4, wherein an end of a microwire distal from the substrate comprises one or more silicon-based semiconductive materials with a different band-gap forming a cap on the microwire forming a buried junction.

9. The microstructure of claim 8, wherein the one or more silicon-based semiconductive materials at the end of the microwire is an amorphous p⁺-type (or n⁺-type, respectively) silicon material.

10. The microstructure of claim 9, further comprising an additional undoped and then n-type (or p-type, respectively) amorphous silicon.

11. The microstructure of claim 1, wherein a portion of the array of microwires is embedded in a polymer, glass, or wax.

12. The microstructure of claim 7, wherein a portion of the array of microwires is embedded in a polymer, glass or wax.

13. The microstructure of claim 11, wherein the polymer is a conductive polymer.

14. The microstructure of claim 8, wherein the cap further comprises a metal catalyst for performing electrochemical fuel-forming reactions.

15. A wire array structure for converting solar energy to electricity comprising:
(a) a plurality of semiconductor silicon microwires each comprising 500 nm to about 10 micrometers in diameter and about 1 micrometer to 1 mm in length; and
(b) a silicon layer deposited on said plurality of wires, said layer comprising a wider band-gap than the silicon microwires and forming a p-n junction with the microwire, wherein said layer is conformal to said plurality of wires.

16. A solar cell comprising the structure of claim 1.

17. A device or photocell comprising:
a substrate;
an ordered array of elongate semiconductor structures, wherein the elongate semiconductor structures have length dimensions defined by adjacent ends in electrical contact with at least portions of the substrate and distal ends not in contact with the substrate and have radial dimensions generally normal to the length dimensions and the radial dimensions are less than the length dimensions; and
a silicon material layer coated on the elongated semiconductor structure to for a p-n junction, wherein at least some portions of the layer are in electrical contact with one or more elongate semiconductor structures of the plurality of the elongate semiconductor structures along at least portions of the length dimensions of the one or more elongate semiconductor structures,
wherein the device absorbs received light and converts it into electricity or chemical fuels via electrochemical reactions at their surfaces.

18. The device or photocell of claim 17, wherein the elongated semiconductor structures comprise wires.

19. The device or photocell of claim 17, wherein the elongate semiconductor structures are grown from the substrate; deposited on the substrate; or formed by etching the substrate.

20. The device or photocell of claim 17, wherein the elongate semiconductor structures are embedded in a matrix.
